(19) United States
(12) Patent Application Publication
(10) Pub. No.: US 2026/0190728 A1
(43) Pub. Date: Jul. 2, 2026

(54) DISPLAY PANEL AND DISPLAY DEVICE

(71) Applicant: HKC CORPORATION LIMITED, Shenzhen (CN)

(72) Inventors: Yao Li, Shenzhen (CN); Pei Xu, Shenzhen (CN)

(21) Appl. No.: 19/424,009

(22) Filed: Dec. 17, 2025

(30) Foreign Application Priority Data
Jan. 2, 2025 (CN) 202510004283.5

(51) Int. Cl. H10K 59/35; H10K 59/122; H10K 59/80

(52) U.S. Cl. CPC H10K 59/351; H10K 59/122; H10K 59/8792

(57) ABSTRACT

Disclosed in the present disclosure is a display panel and a display device. The display panel includes a substrate, a pixel-defining layer, a plurality of light-emitting elements, a compensation light source, an encapsulation layer, and a light-shielding layer. The light-shielding layer is disposed on the compensation light source and located in a non-opening area for blocking outgoing light emitted perpendicular to the substrate from the compensation light source. The compensation light source is configured to provide preset angle compensation outgoing light to the plurality of light-emitting elements when two adjacent light-emitting elements are displayed, where an area of the compensation outgoing light varies with the light emitting intensity of adjacent light-emitting elements. At least one first compensation light source and one second compensation light source are arranged between two adjacent light-emitting elements.

### CROSS REFERENCE TO RELATED APPLICATIONS

The present disclosure claims the priority and benefit of Chinese Patent Application No. 2025100042835, titled "DISPLAY PANEL AND DISPLAY DEVICE" and filed on January 2, 2025 with China National Intellectual Property Administration, the entire contents of which are incorporated herein by reference.

### TECHNICAL FIELD

The present disclosure relates to the technical field of display, and particularly to a display panel and a display device.

### BACKGROUND

As a self-emissive display technology, OLED is increasingly applied in products. With growing public attention to privacy protection in modern society, adjustable viewing angle functionality (also known as anti-peeping) for display devices has become an essential feature. Therefore, OLED adjustable viewing angle technology has recently emerged as a key discussion topic.

Conventional anti-peeping displays attach anti-peeping films onto the display panel surface. Such films typically employ ultra-fine micro-louver technology, operating similarly to vertical blinds. This approach limits light emission from fixed angles on the display panel, representing the most straightforward solution with relatively high yield and wide application. However, anti-peeping films generally offer limited and non-adjustable viewing angles and protection levels. In conventional OLED products, viewing angle adjustment is primarily achieved by controlling the pixel opening area. Yet such adjustment methods remain fixed and often cause reduced luminance issues.

### SUMMARY

An object of the present disclosure is to provide a display panel and a display device that implement wide or narrow viewing angle adjustment through a compensation light source, thereby improving wide-viewing-angle display performance without affecting normal display.

Disclosed in the present disclosure is a display panel. The display panel includes a substrate, a pixel-defining layer, a plurality of light-emitting elements, a compensation light source, an encapsulation layer, and a light-shielding layer. The pixel-defining layer is disposed on the substrate and forms a plurality of opening areas. The plurality of light-emitting elements are disposed on the substrate and located in the opening areas. The compensation light source is disposed on the pixel-defining layer and located in a non-opening area. The encapsulation layer covers the plurality of light-emitting elements and seals the plurality of light-emitting elements. The light-shielding layer is disposed on the compensation light source and located in the non-opening area for blocking outgoing light emitted perpendicular to the substrate from the compensation light source. The compensation light source is configured to provide compensation outgoing light in a preset angle to the light-emitting elements when two adjacent light-emitting elements are displaying, where an area of the compensation outgoing light varies with light emitting intensity of adjacent light-emitting elements. The compensation light source includes a first compensation light source and a second compensation light source. The first compensation light source and the second compensation light source are arranged between every two adjacent light-emitting elements. The first compensation light source is configured to compensate for the plurality of light-emitting elements adjacent thereto. The second compensation light source is configured to compensate for the plurality of light-emitting elements adjacent thereto.

Disclosed in the present disclosure is further a display device comprising a driving circuit and the aforementioned display panel, where the driving circuit is configured to drive the display panel to display.

By respectively disposing the first compensation light source and the second compensation light source in the non-opening area, the first compensation light source and the second compensation light source compensate light-emitting elements on both sides of the non-opening area respectively. Taking one side as an example, the first compensation light source emits light from the non-opening area, and outgoing light perpendicular to the substrate is blocked by the light-shielding layer, causing light emitted by the compensation light source to obliquely emit from the opening area. This forms compensation outgoing light at a specific angle, thereby implementing luminance compensation at certain viewing angles for light-emitting elements adjacent to the first compensation light source. The compensation light source compensates for light emission at large viewing angles when it is required to display in a wide-viewing-angle. Thus, wide or narrow viewing angle adjustment of the display panel is achieved by utilizing the compensation light source, enabling clear visibility of displayed content even at large viewing angles and improving display quality. Moreover, the compensation outgoing light emitted by the compensation light source in the present disclosure may be adjusted according to the intensity of light emitted from adjacent light-emitting elements. This ensures clear display under different screen content conditions, preventing color mixing issues at large viewing angles caused by unadjustable compensation light intensity. The first compensation light source and second compensation light source disposed in the same non-opening area respectively compensate different light-emitting elements particularly when two adjacent light-emitting elements in the same opening area emit different colors. The first and second compensation light sources implement differentiated compensation for respective adjacent units specifically when brightness and color differ between two adjacent light-emitting elements. This achieves variable viewing angle display effects within limited space constraints of the display panel.

### BRIEF DESCRIPTION OF THE DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a schematic diagram of the display panel of the first embodiment of the present disclosure.

FIG. 2 is a schematic diagram of a pixel of the display panel of the present disclosure.

FIG. 3 is another schematic diagram of the display panel of the first embodiment of the present disclosure.

FIG. 4 is a schematic diagram of the display panel of the second embodiment of the present disclosure.

FIG. 5 is another schematic diagram of the display panel of the second embodiment of the present disclosure.

FIG. 6 is a schematic diagram of driving the first non-visible light excitation layer of the present disclosure.

FIG. 7 is a schematic diagram of the display device of the present disclosure.

Reference Numerals: 100, display panel; 101, opening area; 102, non-opening area; 110, substrate; 111, pixel-defining layer; 112, encapsulation layer; 120, light emitting unit; 121, first color light emitting unit; 122, second color light emitting unit; 130, first compensation light source; 131, first light-emitting layer; 1311, first light-emitting section; 1312, second light-emitting section; 132, first non-visible light excitation layer; 1321, first excitation section; 1322, second excitation section; 140, second compensation light source; 141, second light-emitting layer; 1411, third light-emitting section; 1412, fourth light-emitting section; 142, second non-visible light excitation layer; 1421, third excitation section; 1422, fourth excitation section; 150, color filter layer; 151, color filter section; 152, light-shielding layer; R, red sub-pixel; G, green sub-pixel; B, blue sub-pixel; 200, display device; 210, driving circuit.

### DETAILED DESCRIPTION OF EMBODIMENTS

It should be understood that the terminology, specific structures, and functional details disclosed herein are merely used to describe specific embodiments and are illustrative. However, the present disclosure may be implemented through many alternative forms and should not be construed as limited solely to the embodiments described herein.

In the description of the present disclosure, terms such as "first" and "second" are used solely for descriptive purposes and should not be interpreted as indicating relative importance or implicitly specifying the number of technical features indicated. Thus, unless otherwise specified, features qualified by "first" or "second" may explicitly or implicitly include one or more such features. "A plurality of" means two or more. Additionally, directional or positional terms such as "upper," "lower," "left," "right," "vertical," or "horizontal" are described based on orientations or relative positional relationships shown in the accompanying drawings, which are used for simplified description to facilitate understanding of the present application and do not imply that the devices or elements described should have specific orientations or be constructed or operated in specific orientations. These terms should not be construed as limiting the present disclosure. For those skilled in the art, the specific meaning of the above terms in the context of the present disclosure may be understood according to the specific situation.

The present disclosure is described below in detail with reference to the accompanying drawings and optional embodiments.

FIG. 1 is a schematic diagram of the display panel of the first embodiment of the present disclosure. Referring to FIG. 1, disclosed in the present disclosure is a display panel 100. The display panel 100 includes a substrate 110, a pixel-defining layer 111, a plurality of light-emitting elements 120, a compensation light source, an encapsulation layer 112, and a light-shielding layer 152. The pixel-defining layer 111 is disposed on the substrate 110 and forms a plurality of opening areas 101. The plurality of light-emitting elements 120 are disposed on the substrate 110 and located in the plurality of opening areas 101. The compensation light source is disposed on the pixel-defining layer 111 and located in a non-opening area 102. The encapsulation layer 112 covers the light-emitting elements 120 and seals the light-emitting elements 120. The light-shielding layer 152 is disposed on the compensation light source and located in the non-opening area 102 for blocking outgoing light emitted perpendicular to the substrate 110 from the compensation light source. The compensation light source is configured to provide compensation outgoing light in a preset angle to the light-emitting elements 120 when two adjacent light-emitting elements 120 are displaying, where an area of the compensation outgoing light varies with the light emitting intensity of adjacent light-emitting elements 120. The compensation light source includes a first compensation light source 130 and a second compensation light source 140. The first compensation light source 130 and the second compensation light source 140 are arranged between every two adjacent light-emitting elements 120. The first compensation light source 130 is configured to compensate for the plurality of light-emitting elements 120 adjacent thereto. The second compensation light source 140 is configured to compensate for the plurality of light-emitting elements 120 adjacent thereto.

By respectively disposing the first compensation light source 130 and the second compensation light source 140 in the non-opening area 102, the first compensation light source 130 and the second compensation light source 140 compensate light-emitting elements 120 on both sides of the non-opening area 102 respectively. Taking one side as an example, the first compensation light source 130 emits light from the non-opening area 102, and outgoing light perpendicular to the substrate 110 is blocked by the light-shielding layer 152. This causes light emitted by the compensation light source to obliquely emit from the opening areas 101, thereby forming compensation outgoing light at specific angles. This implements luminance compensation at certain viewing angles for the plurality of light-emitting elements 120 adjacent to the first compensation light source 130. When wide-viewing-angle display is required for the display panel 100, the compensation light source compensates for light emission at large viewing angles. Thus, wide or narrow viewing angle adjustment of the display panel 100 is achieved by utilizing the compensation light source, enabling displayed content to be clearly visible even at large viewing angles and improving display quality. Moreover, the compensation outgoing light emitted by the compensation light source in the present disclosure may be adjusted according to light emitting intensity of adjacent light-emitting elements 120. This ensures clear display under different screen content conditions, preventing visibility issues at large viewing angles caused by unadjustable compensation light intensity leading to color mixing. The first compensation light source 130 and second compensation light source 140 disposed in the same non-opening area 102 respectively compensate different light-emitting elements 120 particularly when two adjacent light-emitting elements 120 in the same opening area 101 emit different colors. The first compensation light source 130 and the second compensation light source 140 implement differentiated compensation for respective adjacent light-emitting elements 120 specifically when brightness and color differ between adjacent light-emitting elements 120. This achieves adjustable viewing angle display effects within limited space constraints of the display panel 100.

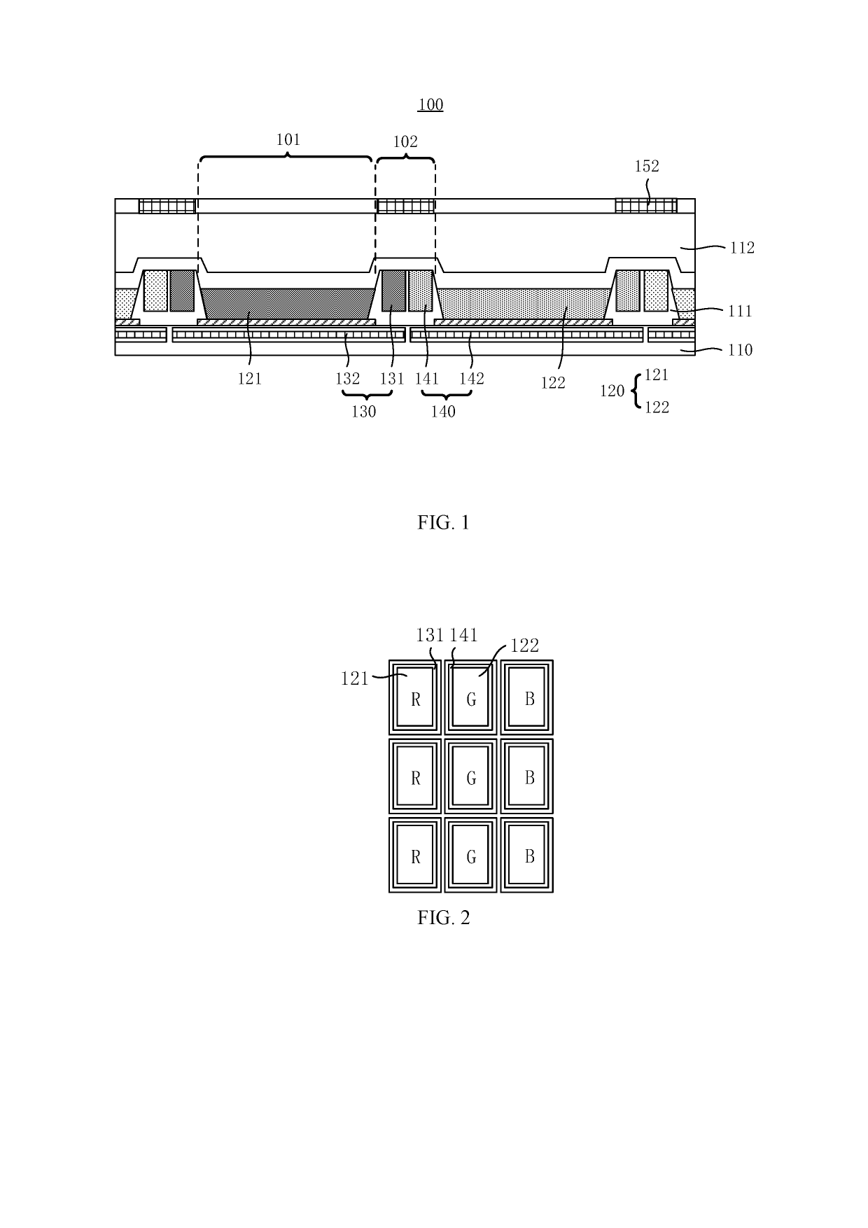

FIG. 2 is a schematic diagram of a pixel of the display panel of the present disclosure. Referring to FIG. 2, the display panel 100 typically divides one pixel into multiple sub-pixel combinations. For example, a pixel may include three components: a red sub-pixel R, a green sub-pixel G, and a blue sub-pixel B. Different gray scales are applied to the red sub-pixel R, green sub-pixel G, and blue sub-pixel B respectively to display different colors. Structurally, sub-pixels of different colors correspond to respective light-emitting elements 120, and the light emitted from light-emitting elements 120 corresponding to different color sub-pixels differs. Under such circumstances, two adjacent light-emitting elements 120 in the non-opening area 102 often emit light of different colors. A compensation light source is unable to adapt to different colors and brightness levels (gray scales) of the two adjacent light-emitting elements 120 when the compensation light source is disposed in the non-opening area 102. This may cause interference with outgoing light from one light emitting unit 120 when compensation light enters the opening area 101 of that unit during luminance compensation for the other light emitting unit 120. It is resolved in the present disclosure by arranging two compensation light sources in one non-opening area 102, with each compensation light source compensating two adjacent light-emitting elements 120 respectively. This allows compensation light to match different luminance levels specifically.

It should be noted that insufficient luminous intensity at side viewing angles causes inaccurate color reproduction for users viewing from such angles when a range of the viewing angle between the human eye and the display panel 100 is less than or equal to 60 degrees. Therefore, compensation for outgoing light at side viewing angles is required. Moreover, compensation outgoing light with corresponding intensity levels is necessary for side viewing angle compensation under different display gray scales, i.e., when luminous intensities from different color light-emitting elements 120 vary. Consequently, the preset angle of the compensation outgoing light provided in the present embodiment primarily targets large viewing angles (typically between 12 and 60 degrees), compensating for display performance within the side viewing angle range.

Specifically, the first compensation light source 130 includes a first non-visible light excitation layer 132 and a first light-emitting layer 131, the second compensation light source 140 includes a second non-visible light excitation layer 142 and a second light-emitting layer 141, the first light-emitting layer 131 and the second light-emitting layer 141 are respectively formed employing a metal organic framework material, the metal organic framework material includes a lanthanide metal, the first light-emitting layer and the second light-emitting layer are configured to generate visible light under non-visible light excitation, and the visible light includes any one of blue light, green light or red light. The first non-visible light excitation layer 132 and the second non-visible light excitation layer 142 are configured to emit non-visible light under voltage driving.

In the present embodiment, a lanthanide metal organic framework material is employed to generate visible light under non-visible light excitation, thereby expanding the display viewing angle. The advantage of the metal organic framework material in the present disclosure lies in its requirement for no voltage supply within the display panel 100, eliminating the need for complex in-plane routing lines. This may be achieved by arranging the first light-emitting layer 131 and the second light-emitting layer 141 in the same layer as the light-emitting elements 120 within the non-opening area 102, and by disposing the corresponding first non-visible light excitation layer 132 and second non-visible light excitation layer 142 below them. By positioning the compensation light source in the non-opening area 102, such as on the pixel-defining layer 111 or at other locations, implementation is straightforward and requires only a small space. Compared to exemplary techniques where compensation light sources are synchronously arranged in the non-opening area 102 utilizing the light-emitting elements 120, the present approach does not require occupying excessive area nor necessitates modifications to the non-opening locations within that pixel. Moreover, due to the area occupied by the devices of the light-emitting elements 120, utilizing light-emitting elements 120 in the non-opening area 102 requires compressing the area of the opening areas 101. When three sub-pixels originally form one pixel, incorporating a compensation sub-pixel within that same pixel would occupy additional area. This necessitates setting up four sub-pixels, leading to a reduction in the opening area 101 and potentially causing display issues.

The first light-emitting layer 131 and the second light-emitting layer 141 emit light of different colors;

Specifically, metal-organic framework materials are porous materials formed by the self-assembly of metal ions with organic ligands. Both the metal ions and the organic ligands may serve as potential luminescent centers, and the pores of MOFs may also accommodate luminescent guests. In the present embodiment, the metal-organic framework material may emit monochromatic light or multicolor light. Under excitation by non-visible light, adding different organic ligands or metal ions results in the emission of light of varying colors. For example, lanthanide metal ions (e.g., Ln³⁺, Eu³⁺, Tb³⁺, and Dy³⁺) and organic ligands with non-uniformly distributed carboxyl groups (e.g., isophthalic acid derivatives) first assemble into belt-like structures through anisotropic growth of the metal ions and organic ligands. These nanobands then entwine and undergo gelation to form a MOF gel. Full-color emission from a mixed-metal MOF gel may be prepared by adjusting the type and/or proportion of Ln³⁺ ions. The coordination center lanthanide metal ions (Eu³⁺, Tb³⁺, or Dy³⁺) may produce emissions of different colors, thereby enabling controllable multicolor output under excitation at the same wavelength. Simultaneously, by varying the types and proportions of ions, emission of the same color at different excitation wavelengths may be achieved.

In the present embodiment, the metal-organic framework material is primarily a lanthanide metal-organic framework material. Lanthanide metal-organic framework materials possess the characteristic of emitting light under non-visible light excitation and may luminesce in various forms. These include, for example, simultaneous luminescence from both the ligand and the metal ions, simultaneous luminescence from both the host and the guest, simultaneous luminescence from mixed metals, and simultaneous luminescence from mixed MOFs. Taking simultaneous luminescence from the ligand and metal ions as an example, the lanthanide metal ions within the lanthanide organic framework material exhibit the antenna effect. This entails the ligand absorbing energy to reach an excited state, followed by intersystem crossing to the triplet state. The triplet state then sensitizes the lanthanide ions, achieving luminescence via the antenna effect. To achieve simultaneous luminescence from the ligand and metal ions, the energy transfer efficiency from the ligand to the europium ions may be modulated by introducing boronic acid groups onto terephthalic acid. Utilizing simultaneous luminescence from the ligand and metal ions, and leveraging the strong affinity of boronic acid groups towards fluoride ions and H₂O₂, ratiometric luminescent sensing and visual detection of fluoride ions and H₂O₂ are achieved. Differing from modulating energy transfer, aggregation-induced emission ligands and lanthanide ions are used to prepare MOFs. These MOFs enhance luminescence by restricting the intramolecular rotation of the ligand via coordination. Combining this with the antenna effect luminescence of europium ions enables the simultaneous enhanced luminescence of both the ligand and the europium ions. For example, by adjusting the proportion of lanthanide ions and ligands, taking Ln-MOF[TbₓEu₁₋ₓ(TCBA)(H₂O)]₂·DMF as an example: Eu(III) is characterized by emitting red light, Tb(III) is characterized by emitting green light, and Gd(III) is characterized by emitting blue light. By adjusting the proportions of Eu(III), Tb(III), and Gd(III), changes in luminescence color may be achieved. That is, by combining different ligands with metal ions, MOFs emitting different colors of light may be realized. Whereas for simultaneous host-guest luminescence, mixed metal luminescence, and mixed MOFs luminescence, the employed ligands and metal ions typically differ. Taking simultaneous host-guest luminescence as an example with Ru@MIL-NH₂ material: Ru(bpy)₃²⁺exhibits red fluorescence, and MIL-NH₂ exhibits blue fluorescence. Under single wavelength excitation at 300 nm, the MOF achieves blue-red host-guest luminescence. Simultaneous mixed metal luminescence may be prepared by utilizing Ln³⁺ ions having similar atomic radii and coordination modes; mixed lanthanide metal MOFs may be easily prepared by adjusting the proportion of Ln³⁺ ions, . Simultaneous mixed MOFs luminescence uses Eu³⁺ and Tb³⁺ as metal nodes, utilizing the red, green, and blue luminescence from Eu³⁺, Tb³⁺, and Dy³⁺, reacting with 2,5-dicarboxyphenylboronic acid to prepare red-emitting Eu-MOFs and green-emitting Tb-MOFs respectively. Together with blue-emitting UiO-66-NH₂, trichromatic MOF ink is prepared.

Besides the four aforementioned luminescence paradigms for achieving multi-luminescent lanthanide metal-organic framework materials, mixed ligands as luminescent centers and single ligands exhibiting multi-luminescence may also be used to prepare multi-luminescent MOFs. Specifically, lanthanide metal-organic framework materials may be made to exhibit different luminescence colors by adjusting the proportions of Eu(III) and Tb(III), Gd(III); the proportions of Eu³⁺, Tb³⁺, and Dy³⁺; and by selecting non-visible light wavelengths between 250 nm and 350 nm. In the present embodiment, the primary utilization involves the lanthanide metal-organic framework material which, under different material ratios, may emit monochromatic light such as red, green, or blue, thereby achieving red light compensation, green light compensation, and blue light compensation.

Specifically, the plurality of light-emitting elements 120 include a plurality of first color light-emitting elements 121 and a plurality of second color light-emitting elements 122, a color of the light emitted from the plurality of first color light-emitting elements 121 is one of red, green or blue, the light emitted from the plurality of second color light-emitting elements 122 is one of red, green or blue, and a color of the light emitted from the plurality of second color light-emitting elements 122 is different from that of the light emitted from the plurality of first color light-emitting elements 121; in a same non-opening area 102, the first light-emitting layer 131 is disposed close to the plurality of first color light-emitting elements 121, the second light-emitting layer 141 is disposed close to the plurality of second color light-emitting elements 122, a color of the light emitted from the first light-emitting layer 131 is consistent with those of the light emitted from the plurality of first color light-emitting elements 121; a color of the light emitted from the second light-emitting layer 141 is consistent with those of the light emitted from the plurality of second color light-emitting elements 122.

The first light-emitting layer 131 and second light-emitting layer 141 in the present embodiment may be made to emit light of different colors by incorporating different lanthanide metal-organic framework materials, thus enabling separate compensation for the first color light-emitting elements 121 and second color light-emitting elements 122 respectively. For example, the light emitted by the first light-emitting layer 131 is red when the first light emitting unit 120 is a red light emitting unit. The light emitted by the second light-emitting layer 141 is green when the second light emitting unit 120 is a green light emitting unit.

It should be noted that while the display panel 100 typically includes light-emitting elements 120 of three colors, the compensation light sources of the present disclosure are disposed between two adjacent light-emitting elements 120 of different colors. When the colors of the plurality of light-emitting elements 120 on either side of a given compensation light source are red/green, red/blue, or blue/green, the first light-emitting layer 131 correspondingly extends differently depending on its specific location. In other words, the colors of the first light-emitting layer 131 and second light-emitting layer 141 in the present embodiment differ across various locations within the non-opening area 102, primarily depending on the colors emitted by the light-emitting elements 120 adjacent to that specific non-opening area 102. The present embodiment defines the first light-emitting layer 131 and second light-emitting layer 141 within the same non-opening area 102. The terms "first" and "second" are used solely to distinguish the position of these light-emitting layers, indicating proximity to the first color light-emitting elements 121 and proximity to the second color light-emitting elements 122, respectively.

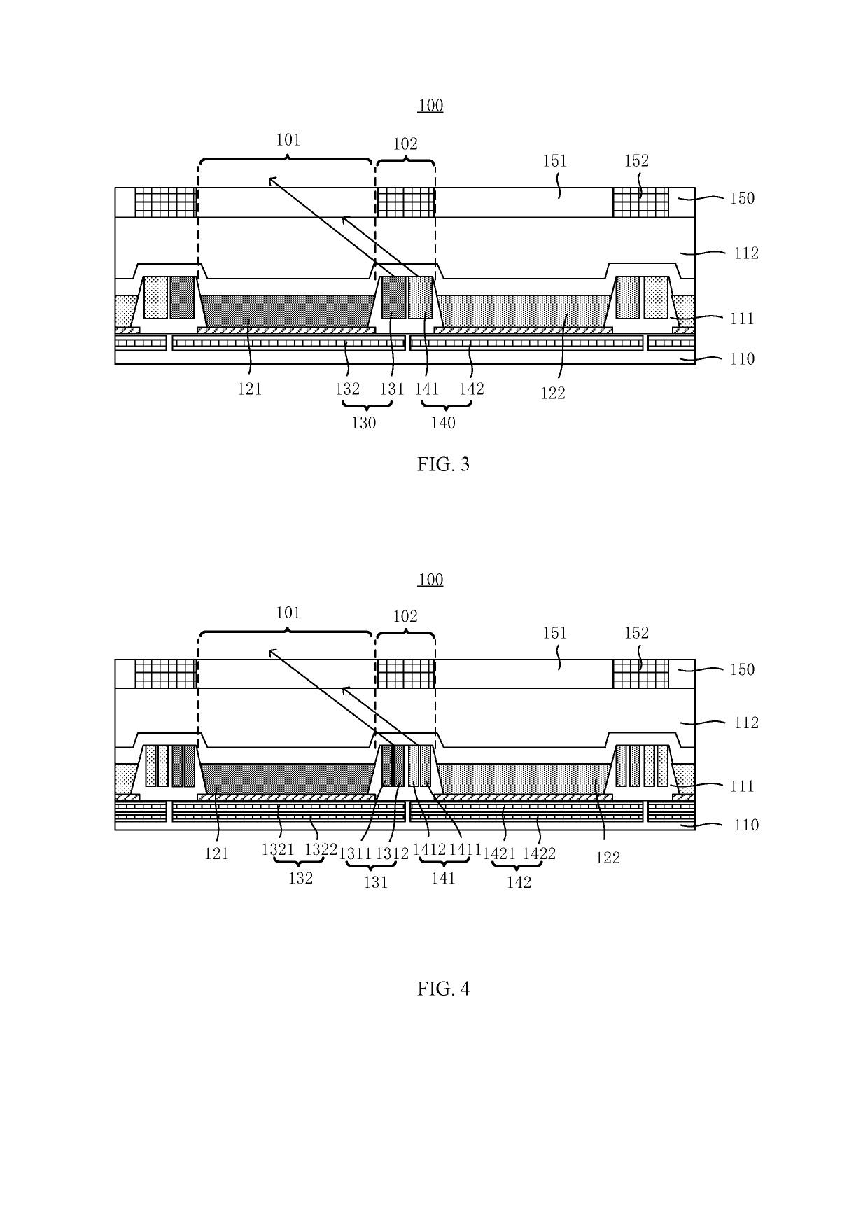

FIG. 3 is another schematic diagram of the display panel according to the first embodiment of the present disclosure. Referring to FIG. 3, in the present embodiment, to further reduce the impact of the first light-emitting layer 131 on the second color light-emitting elements 122, a color filter layer 150 may be disposed on the encapsulation layer 112. The color filter layer 150 includes a plurality of color filter sections 151 corresponding to the plurality of opening areas 101. The color of the color filter section 151 is consistent with the color of the light emitted by the corresponding light emitting unit 120 within each opening area 101. Generally, the color filter sections 151 include a red filter section, a green filter section, and a blue filter section. Three adjacent color filter sections 151 of different colors form one pixel, and are correspondingly referred to as a red sub-pixel R, a green sub-pixel G, and a blue sub-pixel B. The amount of light passing through the red filter section, the green filter section, and the blue filter section is varied by controlling the light emitting intensity of the light-emitting elements 120 at the positions corresponding to the red sub-pixel R, green sub-pixel G, and blue sub-pixel B, thereby achieving color display within the pixel. Any color may be composed within one pixel, that is, display of different colors is achieved by controlling the gray scale of the red sub-pixel R, the gray scale of the green sub-pixel G, and the gray scale of the blue sub-pixel B. Moreover, in the present embodiment, the aforementioned light-shielding layer 152 may be formed in the same layer as the color filter sections 151, utilizing the black matrix within the color filter layer 150 as the light-shielding layer 152.

In the present embodiment, after disposing the color filter layer 150, due to the filtering effect of the color filter sections 151, light emitted by the first light-emitting layer 131 is blocked and absorbed by the color filter section 151 when light emitted by the first light-emitting layer 131 enters the color filter section 151 corresponding to a second color light emitting unit 122, thereby avoiding the impact of the first light-emitting layer 131 on the second color light-emitting elements 122. Combined with the use of the first light-emitting layer 131 and second light-emitting layer 141 of the present disclosure, this reduces the impact on the outgoing light from adjacent light-emitting elements 120 during light compensation.

Specifically, referring to FIGS. 2 to 3, the first light-emitting layer 131 is arranged around the plurality of first color light-emitting elements 121, and the second light-emitting layer 141 is arranged around the plurality of second color light-emitting elements 122.

In the present embodiment, light compensation is provided for side viewing angles all around the first color light-emitting elements 121 since the first light-emitting layer 131 is arranged around the first color light-emitting elements 121. This includes side viewing angles in all four directions—up, down, left, and right—where the light emitted by the first light-emitting layer 131 is visible. Compared to configurations where only a single-color compensation light source is disposed in the non-opening area 102, this significantly enhances the effectiveness of the light compensation.

FIG. 4 is a schematic diagram of the display panel according to the second embodiment of the present disclosure. Referring to FIG. 4, the first light-emitting layer 131 includes a first light-emitting section 1311 and a second light-emitting section 1312; the second light-emitting layer 141 includes a third light-emitting section 1411 and a fourth light-emitting section 1412; the first non-visible light excitation layer 132 includes a first excitation section 1321 and a second excitation section 1322; and the second non-visible light excitation layer 142 includes a third excitation section 1421 and a fourth excitation section 1422. The first light-emitting section 1311 emits first compensation outgoing light under the control of the first excitation section 1321; the second light-emitting section 1312 emits second compensation outgoing light under the control of the second excitation section 1322; the third light-emitting section 1411 emits third compensation outgoing light under the control of the third excitation section 1421; and the fourth light-emitting section 1412 emits fourth compensation outgoing light under the control of the fourth excitation section 1422.

In the present embodiment, the description uses the example where the first light-emitting layer 131 includes the first light-emitting section 1311 and second light-emitting section 1312, but is not limited to the first light-emitting layer 131 having only two light-emitting sections. The present solution primarily addresses the issue that the side viewing angle appears too bright at low gray scales and too dark at high gray scales during high gray scale and low gray scale display, if light-emitting elements 120 at different display gray scales receive the same compensation light. Therefore, in the present embodiment, light compensation for side viewing angles at high gray scales and low gray scales needs to be differentiated. For example, the brightness of the compensation light is greater at high gray scales, while the compensation brightness is smaller at low gray scales, thereby achieving a better compensation effect.

In the present solution, control is primarily achieved by utilizing the non-visible light emitted by the first excitation section 1321 and second excitation section 1322 to make the first light-emitting section 1311 and second light-emitting section 1312 work simultaneously or separately. This implements light compensation brightness with a minimum of two steps. Of course, compensation with more steps of brightness may also be achieved by further increasing the number of light-emitting sections. The third light-emitting section 1411 and fourth light-emitting section 1412 employ the same control method as the first light-emitting section and second light-emitting section to achieve light compensation for the second color light-emitting elements 122.

Specifically, the intensity of the first compensation outgoing light is greater than or equal to that of the second compensation outgoing light, and the intensity of the third compensation outgoing light is greater than or equal to that of the fourth compensation outgoing light.

In the present solution, the luminance of the first light-emitting section 1311 and the second light-emitting section 1312 may be the same or different. In the case where the luminance of the first light-emitting section 1311 and the second light-emitting section 1312 is the same, it is necessary to control the first light-emitting section 1311 and the second light-emitting section 1312 to be activated simultaneously or individually to achieve different compensation luminance levels. In the case where the luminance of the first light-emitting section 1311 and the second light-emitting section 1312 is set to be different, multi-step luminance compensation may be achieved by individually controlling the activation or deactivation of the first light-emitting section 1311 or the second light-emitting section 1312.

Specifically, taking the case where the luminance of the first light-emitting section 1311 and the second light-emitting section 1312 is set to be different as an example, the intensity of the first compensation outgoing light is greater than that of the second compensation outgoing light. The second light-emitting section 1312 operates when the light emitting intensity of the light-emitting elements 120 is within a first range; the first light-emitting section 1311 operates when the light emitting intensity of the light-emitting elements 120 is within a second range. For example, when the display panel 100 displays using 256 gray scales, the display pixels with gray scales from 0 to 127 may be configured with the second light-emitting section 1312 operating, and the display pixels with gray scales from 128 to 255 may be configured with the first light-emitting section 1311 operating. Thus, compensation is performed by the second light-emitting section 1312 during low gray scale display and by the first light-emitting section 1311 during high gray scale display.

Generally, the operation of the first light-emitting section 1311 and the second light-emitting section 1312 needs to be controlled based on the gray scale displayed by adjacent light-emitting elements 120. Control may, of course, also be performed regionally or based on an overall value of the displayed gray scales. For instance, the first light-emitting section 1311 is controlled to operate when over half of the pixels in the current display image exhibit high gray scales; conversely, the second light-emitting section 1312 is controlled to operate when over half of the pixels exhibit low gray scales. Although this overall value control method is relatively not that precise and granular, it possesses strong implementability and offers significant improvement effects for side-viewing angle images.

In one embodiment, the first light-emitting section 1311 is arranged around the first color light-emitting elements 121, the second light-emitting section 1312 is arranged around the first light-emitting section 1311, the third light-emitting section 1411 is arranged around the second color light-emitting elements 122, and the fourth light-emitting section 1412 is arranged around the third light-emitting section 1411, where the intensity of the first compensation outgoing light is equal to that of the second compensation outgoing light, and the intensity of the third compensation outgoing light is equal to that of the fourth compensation outgoing light.

In the present embodiment, taking the first light-emitting layer 131 as an example, the first light-emitting section 1311 and the second light-emitting section 1312 are arranged in the same layer. By arranging the first light-emitting section 1311 and the second light-emitting section 1312 in the same layer, different viewing angle compensation effects may be achieved when individually activating the first light-emitting section 1311 or the second light-emitting section 1312. The light emitted by the second light-emitting section 1312 exhibits a larger angle of inclination since the second light-emitting section 1312 is disposed on a side of the first light-emitting section 1311 away from the first color light-emitting elements 121, enabling compensation light emission at larger angles. In the present embodiment, switching between simultaneous or individual operation of the first light-emitting section 1311 and the second light-emitting section 1312 may be performed, thereby enabling compensation for different viewing angles.

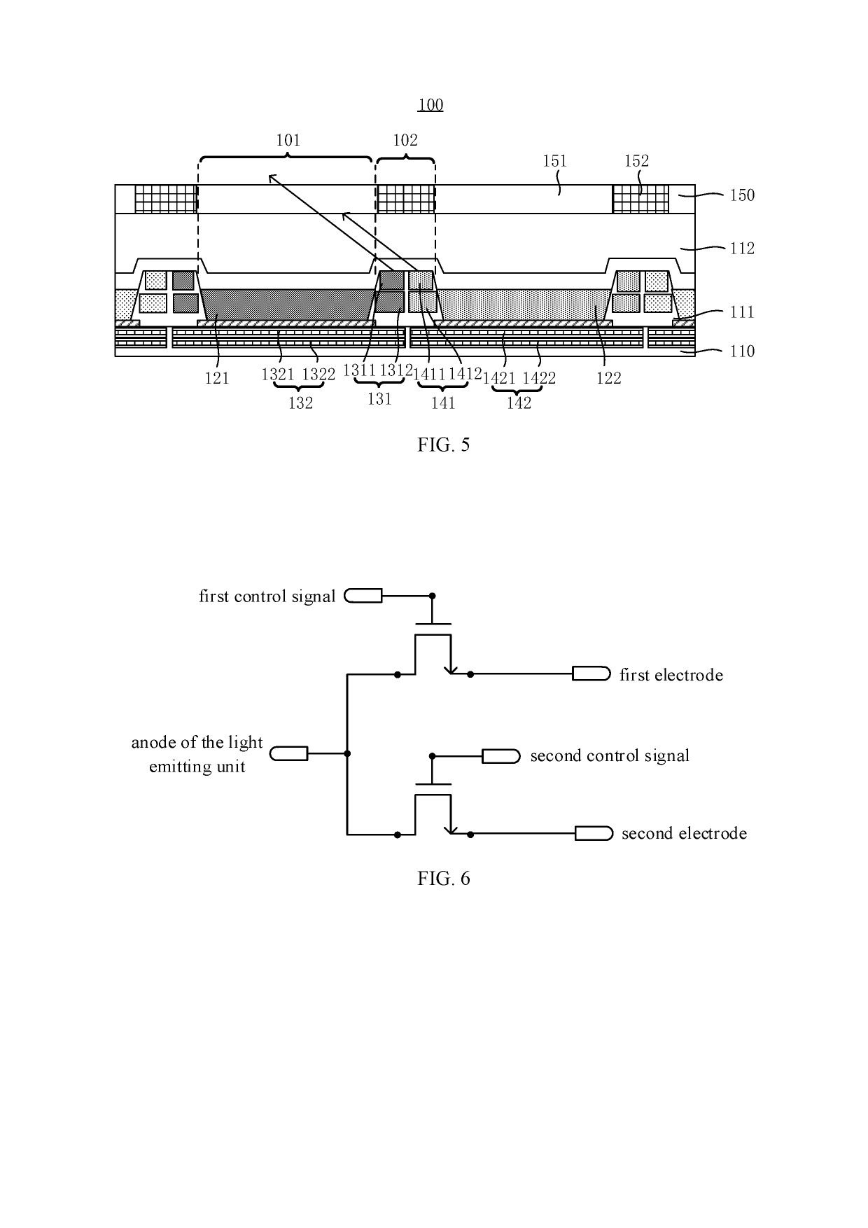

FIG. 5 is another schematic diagram of the display panel according to the second embodiment of the present disclosure. Referring to FIG. 5, in another embodiment, the first light-emitting section 1311 and the second light-emitting section 1312 are arranged in a stacked configuration, with the first light-emitting section 1311 disposed below the second light-emitting section 1312; the third light-emitting section 1411 and the fourth light-emitting section 1412 are arranged in a stacked configuration, with the third light-emitting section 1411 disposed below the fourth light-emitting section 1412; the intensity of the first compensation outgoing light is greater than or equal to that of the second compensation outgoing light, and the intensity of the third compensation outgoing light is greater than or equal to that of the fourth compensation outgoing light.

In the present embodiment, considering that the display panel 100 generally possesses multiple gray scales ranging from 0 to 255, the present disclosure achieves light compensation of different intensities by employing the first light-emitting section 1311 and the second light-emitting section 1312 arranged in a stacked configuration when the display panel 100 displays using different gray scales. For example, the number of activated light-emitting sections may be controlled to achieve step-by-step luminance compensation if the intensity of the first compensation outgoing light is equal to that of the second compensation outgoing light. Furthermore, multi-step compensation may be implemented by arranging multiple light-emitting sections. For instance, the first light-emitting section 1311 and the second light-emitting section 1312 may be individually controlled to emit light separately or simultaneously if the intensity of the first compensation outgoing light is greater than that of the second compensation outgoing light, thereby achieving light compensation with at least three steps. It should be understood that the number of non-visible light excitation layers may be correspondingly increased to synchronize the control of the light-emitting sections with the increase in the number of light-emitting sections. When sufficient space is available in the non-opening area 102, the plurality of light-emitting sections may be arranged by configuring the first light-emitting section 1311 and the second light-emitting section 1312 both in the same layer and in a stacked configuration, thereby achieving multi-step and multi-angle light compensation.

Specifically, regarding the configurations of the first non-visible light excitation layer 132 and the second non-visible light excitation layer 142, the first non-visible light excitation layer 132 is disposed below the first color light-emitting elements 121, the first non-visible light excitation layer 132 overlaps with the first light-emitting layer 131 under an orthographic projection on the substrate 110, the first excitation section 1321 and the second excitation section 1322 are arranged in a stacked configuration, the first excitation section 1321 is disposed below the second excitation section 1322, the first excitation section 1321 and the second excitation section 1322 emit non-visible light of different wavelengths, the second non-visible light excitation layer 142 is disposed below the second color light-emitting elements 122, the second non-visible light excitation layer 142 overlaps with the second light-emitting layer 141 under the orthographic projection on the substrate 110, the third excitation section 1421 and the fourth excitation section 1422 are arranged in a stacked configuration, the third excitation section is 1421 disposed below the fourth excitation section 1422, the third excitation section 1421 and the fourth excitation section 1422 emit non-visible light of different wavelengths.

FIG. 6 is a schematic diagram of driving the first non-visible light excitation layer of the present disclosure. Referring to FIGS. 4 to 6, in the present embodiment, the first non-visible light excitation layer 132 and the second non-visible light excitation layer 142 may be arranged in the same layer, and located between the substrate 110 and the light-emitting elements 120 or on a side of the substrate 110 away from the light-emitting elements 120. Specifically, taking the first non-visible light excitation layer 132 as an example, for driving the first excitation section 1321 and the second excitation section 1322, the first excitation section 1321 and the second excitation section 1322 need to be activated or deactivated simultaneously with the corresponding light emitting unit 120. The first excitation section 1321 and the second excitation section 1322 respectively require two electrodes for driving. However, considering that the first excitation section 1321 and the second excitation section 1322 are arranged in a stacked configuration, the first excitation section 1321 and the second excitation section 1322 may share one common electrode. Driving is then achieved by controlling the other electrode for the first excitation section 1321 and the second excitation section 1322. Taking the other electrode for the first excitation section 1321 as a first electrode and for the second excitation section 1322 as a second electrode as an example: The first excitation section 1321 is driven employing a first active switch. The gate of the first active switch is connected to a first control signal. The input terminal of the first active switch is connected to the anode (bottom electrode) of the corresponding light emitting unit 120. The output terminal of the first active switch is connected to the first electrode. The second excitation section 1322 is driven employing a second active switch. The gate of the second active switch is connected to a second control signal. The input terminal of the second active switch is connected to the anode of the aforementioned light emitting unit 120. The output terminal of the second active switch is connected to the second electrode. Under the control of the first control signal and the second control signal, the first excitation section 1321 or the second excitation section 1322 may be controlled to operate when the aforementioned light emitting unit 120 emits light. The first control signal and the second control signal are primarily determined based on the gray scale of the display image. It is worth mentioning that integral blocks of the first excitation section 1321 and the second excitation section 1322 may be disposed below the light emitting unit 120. These blocks extend from one side of the light emitting unit 120 to the other side, ensuring that the first light-emitting section 1311 and the second light-emitting section 1312, arranged peripherally around the light emitting unit 120 within the surrounding non-opening area 102, are collectively controlled by the same first excitation section 1321 and second excitation section 1322, thereby leading to a reduction in manufacturing complexity.

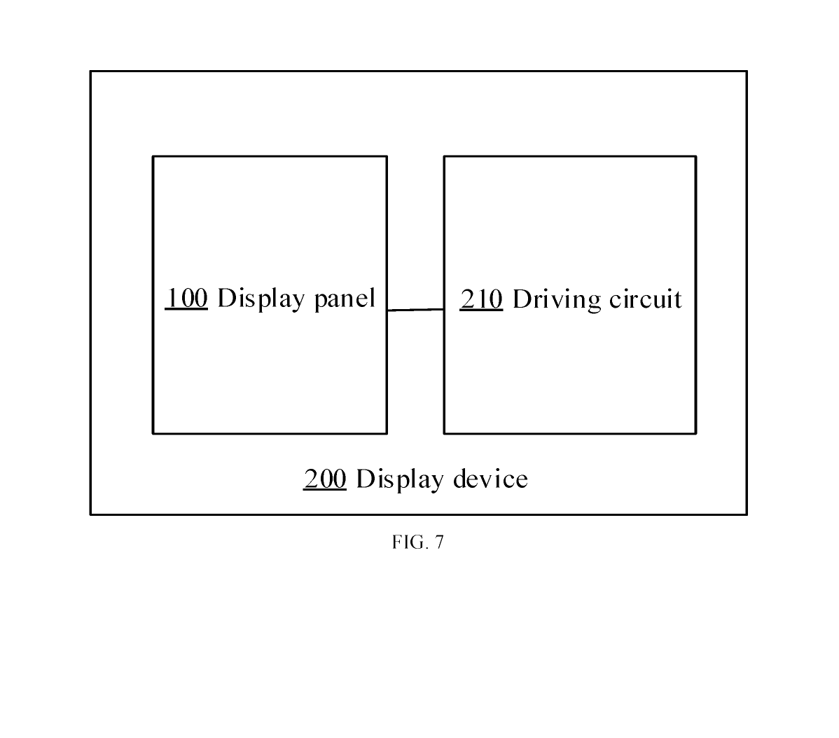

FIG. 7 is a schematic diagram of the display device of the present disclosure. Referring to FIG. 7, the present disclosure further discloses a display device 200. The display device 200 includes a driving circuit 210 and the display panel 100 according to any one of the foregoing embodiments. The driving circuit 210 is configured to drive the display panel 100 to display.

It should be noted that the inventive concept of the present disclosure may be formed into many embodiments, but limitations of the application document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail in conjunction with specific optional embodiments, but it should not be construed that the specific implementation of the present disclosure is limited solely to these descriptions. For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. A display panel, comprising:
a substrate;
a pixel-defining layer, disposed on the substrate, forming a plurality of opening areas;
a plurality of light-emitting elements, disposed on the substrate, located in the plurality of opening areas respectively;
a compensation light source, disposed on the pixel-defining layer, located in a non-opening area;
an encapsulation layer, covering the plurality of light-emitting elements, configured to seal the plurality of light-emitting elements; and
a light-shielding layer, disposed on the compensation light source, and located in the non-opening area, configured to block outgoing light emitted perpendicular to the substrate from the compensation light source,
wherein the compensation light source is configured to provide compensation outgoing light in a preset angle to the plurality of light-emitting elements when two adjacent light-emitting elements of the plurality of light-emitting elements emit light for display, an area of the compensation outgoing light varies with light emitting intensity of adjacent light-emitting elements;
wherein the compensation light source comprises a plurality of first compensation light sources and a plurality of second compensation light sources, at least one first compensation light source and at least one second compensation light source are disposed between every two adjacent light-emitting elements, each of the plurality of first compensation light sources is configured to compensate for at least one of the plurality of light-emitting elements adjacent thereto; and each of the plurality of second compensation light sources is configured to compensate for at least one of the plurality of light-emitting elements adjacent thereto.

2. The display panel according to claim 1, wherein the first compensation light source comprises a first non-visible light excitation layer and a first light-emitting layer, the second compensation light source comprises a second non-visible light excitation layer and a second light-emitting layer,
the first light-emitting layer and the second light-emitting layer are respectively formed employing a metal organic framework material, the metal organic framework material comprises a lanthanide metal, the first light-emitting layer and the second light-emitting layer are configured to generate visible light under non-visible light excitation, and the visible light comprises any one of blue light, green light or red light.

3. The display panel according to claim 2, wherein the first light-emitting layer and the second light-emitting layer emit light of different colors;
the first non-visible light excitation layer and the second non-visible light excitation layer are configured to emit non-visible light under voltage driving.

4. The display panel according to claim 3, wherein the plurality of light-emitting elements comprise a plurality of first color light-emitting elements and a plurality of second color light-emitting elements, a color of the light emitted from the plurality of first color light-emitting elements is one of red, green or blue, the light emitted from the plurality of second color light-emitting elements is one of red, green or blue, and a color of the light emitted from the plurality of second color light-emitting elements is different from that of the light emitted from the plurality of first color light-emitting elements;
in a same non-opening area, the first light-emitting layer is disposed close to the plurality of first color light-emitting elements, the second light-emitting layer is disposed close to the plurality of second color light-emitting elements, a color of the light emitted from the first light-emitting layer is consistent with those of the light emitted from the plurality of first color light-emitting elements; a color of the light emitted from the second light-emitting layer is consistent with those of the light emitted from the plurality of second color light-emitting elements.

5. The display panel according to claim 4, wherein the first light-emitting layer is arranged around the plurality of first color light-emitting elements, and the second light-emitting layer is arranged around the plurality of second color light-emitting elements.

6. The display panel according to claim 5, wherein the first light-emitting layer comprises a first light-emitting section and a second light-emitting section, the second light-emitting layer comprises a third light-emitting section and a fourth light-emitting section, the first non-visible light excitation layer comprises a first excitation section and a second excitation section, the second non-visible light excitation layer comprises a third excitation section and a fourth excitation section,
the first light-emitting section emits first compensation outgoing light under control of the first excitation section, the second light-emitting section emits second compensation outgoing light under control of the second excitation section,
the third light-emitting section emits third compensation outgoing light under control of the third excitation section, and the fourth light-emitting section emits fourth compensation outgoing light under control of the fourth excitation section,
wherein an intensity of the first compensation outgoing light is greater than or equal to that of the second compensation outgoing light, and an intensity of the third compensation outgoing light is greater than or equal to that of the fourth compensation outgoing light.

7. The display panel according to claim 6, wherein the first light-emitting section is arranged around the first color light-emitting elements, the second light-emitting section is arranged around the first light-emitting section,
the third light-emitting section is arranged around the second color light-emitting elements, and the fourth light-emitting section is arranged around the third light-emitting section,
wherein the intensity of the first compensation outgoing light is equal to that of the second compensation outgoing light, and the intensity of the third compensation outgoing light is equal to that of the fourth compensation outgoing light.

8. The display panel according to claim 6, wherein the first light-emitting section and the second light-emitting section are arranged in a stacked configuration, the first light-emitting section is disposed below the second light-emitting section,
the third light-emitting section and the fourth light-emitting section are arranged in a stacked configuration, the third light-emitting section is disposed below the fourth light-emitting section,
the intensity of the first compensation outgoing light is greater than or equal to that of the second compensation outgoing light, and the intensity of the third compensation outgoing light is greater than or equal to that of the fourth compensation outgoing light.

9. The display panel according to claim 6, wherein the first non-visible light excitation layer is disposed below the first color light-emitting elements, the first non-visible light excitation layer overlaps with the first light-emitting layer under an orthographic projection on the substrate,
the first excitation section and the second excitation section are arranged in a stacked configuration, the first excitation section is disposed below the second excitation section, the first excitation section and the second excitation section emit non-visible light of different wavelengths,
the second non-visible light excitation layer is disposed below the second color light-emitting elements, the second non-visible light excitation layer overlaps with the second light-emitting layer under the orthographic projection on the substrate,
the third excitation section and the fourth excitation section are arranged in a stacked configuration, the third excitation section is disposed below the fourth excitation section, the third excitation section and the fourth excitation section emit non-visible light of different wavelengths.

10. The display panel according to claim 5, wherein the display panel further comprises a color filter layer, the color filter layer is disposed on the encapsulation layer, the color filter layer is provided with a plurality of color filter sections corresponding to the the plurality of opening area, and a color of each of the plurality of color filter sections is consistent with that of light emitted from a corresponding light emitting unit in each of the plurality of opening areas.

11. The display panel according to claim 1, wherein a range of the preset angle is from 12 degrees to 60 degrees.

12. A display device, comprising a driving circuit and a display panel, wherein the driving circuit is configured to drive the display panel to display, the display panel comprises:
a substrate;
a pixel-defining layer, disposed on the substrate, forming a plurality of opening areas;
a plurality of light-emitting elements, disposed on the substrate, located in the plurality of opening areas respectively;
a compensation light source, disposed on the pixel-defining layer, located in a non-opening area;
an encapsulation layer, covering the plurality of light-emitting elements, configured to seal the plurality of light-emitting elements; and
a light-shielding layer, disposed on the compensation light source, and located in the non-opening area, configured to block outgoing light emitted perpendicular to the substrate from the compensation light source,
wherein the compensation light source is configured to provide compensation outgoing light in a preset angle to the plurality of light-emitting elements when two adjacent light-emitting elements of the plurality of light-emitting elements emit light for display, an area of the compensation outgoing light varies with light emitting intensity of adjacent light-emitting elements;
wherein the compensation light source comprises a plurality of first compensation light sources and a plurality of second compensation light sources, at least one first compensation light source and at least one second compensation light source are disposed between every two adjacent light-emitting elements, each of the plurality of first compensation light sources is configured to compensate for at least one of the plurality of light-emitting elements adjacent thereto; and each of the plurality of second compensation light sources is configured to compensate for at least one of the plurality of light-emitting elements adjacent thereto.

13. The display panel according to claim 12, wherein the first compensation light source comprises a first non-visible light excitation layer and a first light-emitting layer, the second compensation light source comprises a second non-visible light excitation layer and a second light-emitting layer,
the first light-emitting layer and the second light-emitting layer are respectively formed employing a metal organic framework material, the metal organic framework material comprises a lanthanide metal, the first light-emitting layer and the second light-emitting layer are configured to generate visible light under non-visible light excitation, and the visible light comprises any one of blue light, green light or red light.

14. The display panel according to claim 13, wherein the first light-emitting layer and the second light-emitting layer emit light of different colors;
the first non-visible light excitation layer and the second non-visible light excitation layer are configured to emit non-visible light under voltage driving.

15. The display panel according to claim 14, wherein the plurality of light-emitting elements comprise a plurality of first color light-emitting elements and a plurality of second color light-emitting elements, a color of the light emitted from the plurality of first color light-emitting elements is one of red, green or blue, the light emitted from the plurality of second color light-emitting elements is one of red, green or blue, and a color of the light emitted from the plurality of second color light-emitting elements is different from that of the light emitted from the plurality of first color light-emitting elements;
in a same non-opening area, the first light-emitting layer is disposed close to the plurality of first color light-emitting elements, the second light-emitting layer is disposed close to the plurality of second color light-emitting elements, a color of the light emitted from the first light-emitting layer is consistent with those of the light emitted from the plurality of first color light-emitting elements; a color of the light emitted from the second light-emitting layer is consistent with those of the light emitted from the plurality of second color light-emitting elements.

16. The display panel according to claim 15, wherein the first light-emitting layer is arranged around the plurality of first color light-emitting elements, and the second light-emitting layer is arranged around the plurality of second color light-emitting elements.
